(19) United States
(12) Patent Application Publication
(10) Pub. No.: US 2021/0325468 A1
(43) Pub. Date: Oct. 21, 2021

(54) PARAMETER ESTIMATION SYSTEM, PARAMETER ESTIMATION DEVICE, VEHICLE, COMPUTER PROGRAM, AND PARAMETER ESTIMATION METHOD

(71) Applicant: SUMITOMO ELECTRIC INDUSTRIES, LTD., Osaka-shi, Osaka (JP)

(72) Inventor: Tomomi KATAOKA, Osaka-shi (JP)

(73) Assignee: SUMITOMO ELECTRIC INDUSTRIES, LTD., Osaka-shi, Osaka (JP)

(21) Appl. No.: 17/273,697

(22) PCT Filed: Oct. 15, 2019
(86) PCT No.: PCT/JP2019/040390

§ 371 Date: Mar. 4, 2021

(30) Foreign Application Priority Data
Oct. 30, 2018 (JP) 2018-204374

(51) Int. Cl. G01R 31/367; G01R 31/3842; H01M 10/48; H02J 7/00

(52) U.S. Cl. CPC G01R 31/367; G01R 31/3842; H02J 7/00716; H02J 7/00034; H02J 7/0048; H01M 10/482

(57) ABSTRACT

A first parameter estimation device includes a sequential estimation unit configured to sequentially estimate parameters of an equivalent circuit of a secondary battery on the basis of a current and a voltage of the secondary battery when charging or discharging of the secondary battery has been performed on the basis of a current pattern. A second parameter estimation device includes: a collective estimation unit configured to collectively estimate parameters of the equivalent circuit of the secondary battery on the basis of a current and a voltage having been collected; and an output unit configured to output the estimated parameters to the first parameter estimation device. The first parameter estimation device further includes an update unit configured to update the sequentially estimated parameters with the collectively estimated parameters.

### TECHNICAL FIELD

The present disclosure relates to a parameter estimation system, a parameter estimation device, a vehicle, a computer program, and a parameter estimation method.

This application claims priority on Japanese Patent Application No. 2018-204374 filed on Oct. 30, 2018, the entire content of which is incorporated herein by reference.

### BACKGROUND ART

In recent years, vehicles such as hybrid electric vehicles (HEVs) and electric vehicles (EVs) are becoming prevalent. HEVs and EVs are equipped with secondary batteries. In such vehicles, switching between charging and discharging of the secondary battery is repeated in association with traveling. Since the state of the secondary battery is greatly changed due to charging/discharging during travel of the vehicle, the state of the secondary battery needs to be accurately obtained.

PATENT LITERATURE 1 discloses a battery abnormality diagnostic device that can efficiently identify an abnormality of a secondary battery by performing charging/discharging of the secondary battery in accordance with an appropriate charging/discharging pattern according to information related to an abnormality tendency of the secondary battery acquired before performing battery diagnosis.

### CITATION LIST

### Patent Literature

PATENT LITERATURE 1: Japanese Laid-Open Patent Publication No. 2016-217900

### SUMMARY OF INVENTION

A parameter estimation system according to an embodiment of the present disclosure includes a first parameter estimation device and a second parameter estimation device which estimate parameters of an equivalent circuit of a secondary battery. The first parameter estimation device includes: an acquisition unit configured to acquire a current and a voltage of the secondary battery when charging or discharging of the secondary battery has been performed on the basis of a current pattern; and a sequential estimation unit configured to sequentially estimate the parameters of the equivalent circuit of the secondary battery on the basis of the current and the voltage acquired by the acquisition unit. The second parameter estimation device includes: a collection unit configured to collect the current and the voltage of the secondary battery when charging or discharging of the secondary battery has been performed on the basis of the current pattern; a collective estimation unit configured to collectively estimate the parameters of the equivalent circuit of the secondary battery on the basis of the current and the voltage collected by the collection unit; and an output unit configured to output the parameters estimated by the collective estimation unit to the first parameter estimation device. The first parameter estimation device further includes an update unit configured to update, when the collectively estimated parameters have been acquired from the second parameter estimation device, the sequentially estimated parameters with the collectively estimated parameters.

A parameter estimation device according to the embodiment of the present disclosure is configured to estimate parameters of an equivalent circuit of a secondary battery. The parameter estimation device includes: an acquisition unit configured to acquire a current and a voltage of the secondary battery when charging or discharging of the secondary battery has been performed on the basis of a current pattern; a sequential estimation unit configured to sequentially estimate the parameters of the equivalent circuit of the secondary battery on the basis of the current and the voltage acquired by the acquisition unit; and an update unit configured to update, when collectively estimated parameters of the equivalent circuit of the secondary battery that are based on the current and the voltage of the secondary battery have been acquired in a case where charging or discharging of the secondary battery has been performed on the basis of the current pattern, the sequentially estimated parameters with the collectively estimated parameters.

A vehicle according to the embodiment of the present disclosure includes the parameter estimation device described above.

A parameter estimation device according to the embodiment of the present disclosure is configured to estimate parameters of an equivalent circuit of a secondary battery. The parameter estimation device includes: a collection unit configured to collect a current and a voltage of the secondary battery when charging or discharging of the secondary battery has been performed on the basis of a current pattern; a collective estimation unit configured to collectively estimate the parameters of the equivalent circuit of the secondary battery on the basis of the current and the voltage collected by the collection unit; and an output unit configured to output the parameters estimated by the collective estimation unit.

A computer program according to the embodiment of the present disclosure is configured to cause a computer to estimate parameters of an equivalent circuit of a secondary battery. The computer program causes the computer to execute: a process of collecting a current and a voltage of the secondary battery when charging or discharging of the secondary battery has been performed on the basis of a current pattern; and a process of collectively estimating the parameters of the equivalent circuit of the secondary battery on the basis of the collected current and voltage.

A computer-readable non-transitory storage medium according to the embodiment of the present disclosure has stored therein a computer program for estimating parameters of an equivalent circuit of a secondary battery. The computer program causes a computer to execute: a process of collecting a current and a voltage of the secondary battery when charging or discharging of the secondary battery has been performed on the basis of a current pattern; and a process of collectively estimating the parameters of the equivalent circuit of the secondary battery on the basis of the collected current and voltage.

A parameter estimation method according to the embodiment of the present disclosure is for estimating parameters of an equivalent circuit of a secondary battery. The parameter estimation method includes: acquiring a current and a voltage of the secondary battery when charging or discharging of the secondary battery has been performed on the basis of a current pattern; sequentially estimating the parameters of the equivalent circuit of the secondary battery on the basis of the acquired current and voltage; collecting the current and the voltage of the secondary battery when charging or discharging of the secondary battery has been performed on the basis of the current pattern; collectively estimating the parameters of the equivalent circuit of the secondary battery on the basis of the collected current and voltage; and updating, when the collectively estimated parameters have been acquired, the sequentially estimated parameters with the collectively estimated parameters.

### BRIEF DESCRIPTION OF DRAWINGS

FIG. 1 is a schematic diagram showing an example of a configuration of a parameter estimation system of the present embodiment.

FIG. 2 is a block diagram showing an example of a configuration of a main part of a vehicle having a battery monitoring device installed therein.

FIG. 3 is a block diagram showing an example of a configuration of a server.

FIG. 4 is a schematic diagram showing an example of a process performed in the parameter estimation system of the present embodiment.

FIG. 5 is a schematic diagram showing an example of a test pattern.

FIG. 6 is a schematic diagram showing an example of a relationship between a pattern cycle and a sampling cycle.

FIG. 7 illustrates an example of an equivalent circuit of a secondary battery unit.

FIG. 8 is a block diagram showing an example of a configuration of a parameter estimation unit.

FIG. 9 shows an example of transition of an estimation result of parameters of the equivalent circuit obtained through sequential estimation.

FIG. 10 is a flow chart showing an example of a procedure of a process performed by the battery monitoring device.

FIG. 11 is a flow chart showing an example of a procedure of a process performed by the server.

FIG. 12A is a schematic diagram showing a first example of a communication means between a charger and the battery monitoring device.

FIG. 12B is a schematic diagram showing a second example of a communication means between the charger and the battery monitoring device.

FIG. 12C is a schematic diagram showing a third example of a communication means between the charger and the battery monitoring device.

FIG. 13 is a schematic diagram showing an example of a configuration of a wireless communication frame.

### DESCRIPTION OF EMBODIMENTS

### Problems to be Solved by the Present Disclosure

The device according to PATENT LITERATURE 1 is configured to, when an abnormality tendency of a secondary battery has been detected, efficiently identify the abnormality, and thus, cannot estimate the state of the secondary battery before an abnormality occurs. In addition, in order to accurately estimate the state of the secondary battery, parameters of an equivalent circuit of the secondary battery need to be accurately estimated.

Therefore, an object of the present disclosure is to provide a parameter estimation system, a parameter estimation device, a computer program, and a parameter estimation method that can accurately estimate parameters of an equivalent circuit of a secondary battery.

### Effects of the Present Disclosure

According to the present disclosure, parameters of an equivalent circuit of a secondary battery can be accurately estimated.

### Description of Embodiment of the Present Disclosure

A parameter estimation system according to the present embodiment includes a first parameter estimation device and a second parameter estimation device which estimate parameters of an equivalent circuit of a secondary battery. The first parameter estimation device includes: an acquisition unit configured to acquire a current and a voltage of the secondary battery when charging or discharging of the secondary battery has been performed on the basis of a current pattern; and a sequential estimation unit configured to sequentially estimate the parameters of the equivalent circuit of the secondary battery on the basis of the current and the voltage acquired by the acquisition unit. The second parameter estimation device includes: a collection unit configured to collect the current and the voltage of the secondary battery when charging or discharging of the secondary battery has been performed on the basis of the current pattern; a collective estimation unit configured to collectively estimate the parameters of the equivalent circuit of the secondary battery on the basis of the current and the voltage collected by the collection unit; and an output unit configured to output the parameters estimated by the collective estimation unit to the first parameter estimation device. The first parameter estimation device further includes an update unit configured to update, when the collectively estimated parameters have been acquired from the second parameter estimation device, the sequentially estimated parameters with the collectively estimated parameters.

A parameter estimation device according to the present embodiment is configured to estimate parameters of an equivalent circuit of a secondary battery. The parameter estimation device includes: an acquisition unit configured to acquire a current and a voltage of the secondary battery when charging or discharging of the secondary battery has been performed on the basis of a current pattern; a sequential estimation unit configured to sequentially estimate the parameters of the equivalent circuit of the secondary battery on the basis of the current and the voltage acquired by the acquisition unit; and an update unit configured to update, when collectively estimated parameters of the equivalent circuit of the secondary battery that are based on the current and the voltage of the secondary battery have been acquired in a case where charging or discharging of the secondary battery has been performed on the basis of the current pattern, the sequentially estimated parameters with the collectively estimated parameters.

A vehicle according to the present embodiment includes the parameter estimation device described above.

A parameter estimation device according to the present embodiment is configured to estimate parameters of an equivalent circuit of a secondary battery. The parameter estimation device includes: a collection unit configured to collect a current and a voltage of the secondary battery when charging or discharging of the secondary battery has been performed on the basis of a current pattern; a collective estimation unit configured to collectively estimate the parameters of the equivalent circuit of the secondary battery on the basis of the current and the voltage collected by the collection unit; and an output unit configured to output the parameters estimated by the collective estimation unit.

A computer program according to the present embodiment is configured to cause a computer to estimate parameters of an equivalent circuit of a secondary battery. The computer program causes the computer to execute: a process of collecting a current and a voltage of the secondary battery when charging or discharging of the secondary battery has been performed on the basis of a current pattern; and a process of collectively estimating the parameters of the equivalent circuit of the secondary battery on the basis of the collected current and voltage.

A computer-readable non-transitory storage medium according to the present embodiment has stored therein a computer program for estimating parameters of an equivalent circuit of a secondary battery. The computer program causes a computer to execute: a process of collecting a current and a voltage of the secondary battery when charging or discharging of the secondary battery has been performed on the basis of a current pattern; and a process of collectively estimating the parameters of the equivalent circuit of the secondary battery on the basis of the collected current and voltage.

A parameter estimation method according to the present embodiment is for estimating parameters of an equivalent circuit of a secondary battery. The parameter estimation method includes: acquiring a current and a voltage of the secondary battery when charging or discharging of the secondary battery has been performed on the basis of a current pattern; sequentially estimating the parameters of the equivalent circuit of the secondary battery on the basis of the acquired current and voltage; collecting the current and the voltage of the secondary battery when charging or discharging of the secondary battery has been performed on the basis of the current pattern; collectively estimating the parameters of the equivalent circuit of the secondary battery on the basis of the collected current and voltage; and updating, when the collectively estimated parameters have been acquired, the sequentially estimated parameters with the collectively estimated parameters.

The first parameter estimation device includes: an acquisition unit configured to acquire a current and a voltage of the secondary battery when charging or discharging of the secondary battery has been performed on the basis of a current pattern; and a sequential estimation unit configured to sequentially estimate the parameters of the equivalent circuit of the secondary battery on the basis of the current and the voltage acquired by the acquisition unit.

The secondary battery (also referred to as a secondary battery unit) has a configuration in which a plurality of single unit cells (also referred to as battery cells) or a plurality of sets of unit sells connected in parallel are connected in series. The acquisition unit acquires a charge current or a discharge current of the secondary battery and acquires a voltage of the secondary battery during charging or discharging. The cycle of the current pattern can be determined as appropriate in accordance with the type or the like of the secondary battery, and can be about 200 ms, 500 ms, or 1 s, for example.

As for the parameters of the equivalent circuit of the secondary battery, an equivalent circuit model of the secondary battery can be represented by, for example, a circuit in which a resistor Ra, and a parallel circuit of a resistor Rb and a capacitor Cb are connected in series to a voltage source having an OCV as an electromotive force. In this case, the resistor Ra represents the resistance of an electrolyte bulk, the resistor Rb represents an interface charge transfer resistance, and the capacitor Cb represents an electric double layer capacitance.

The sequential estimation unit sequentially estimates, in each sequential estimation cycle, parameters of the equivalent circuit of the secondary battery. The parameters of the equivalent circuit can be calculated as follows. That is, a least-squares method is applied to a relational expression representing the relationship between the current of the secondary battery, the voltage thereof, and a sampling cycle of acquiring the current and the voltage, to determine coefficients of the relational expression, and the determined coefficients are used to calculate the parameters of the equivalent circuit. In the sequential estimation, this calculation is performed in each sequential estimation cycle. The sequential estimation cycle may be the same as the sampling cycle or may be longer than the sampling cycle (e.g., sampling cycle×2, etc.).

The second parameter estimation device includes: a collection unit configured to collect the current and the voltage of the secondary battery when charging or discharging of the secondary battery has been performed on the basis of the current pattern; a collective estimation unit configured to collectively estimate the parameters of the equivalent circuit of the secondary battery on the basis of the collected current and voltage; and an output unit configured to output the estimated parameters to the first parameter estimation device.

The collection unit collects the current and the voltage of the secondary battery that have been acquired in the sampling cycle. For example, the collection unit collects, over a plurality (e.g., 20 times) of pattern cycles, the current and the voltage of the secondary battery that have been acquired in the sampling cycle.

The collective estimation unit collectively estimates the parameters of the equivalent circuit of the secondary battery on the basis of the collected current and voltage. The sequential estimation is calculation that is performed in each sequential estimation cycle (e.g., in each sampling cycle). In contrast, in the collective estimation, estimation is performed collectively by using all the data of the plurality (e.g., 20 times) of cycles of the current pattern, and thus, the estimation accuracy can be increased.

The first parameter estimation device includes an update unit configured to update, when collectively estimated parameters have been acquired from the second parameter estimation device, the sequentially estimated parameters with the collectively estimated parameters.

Since the update unit updates the parameters of the equivalent circuit estimated by the sequential estimation with the collectively estimated parameters having a higher accuracy, the parameters of the equivalent circuit can be more accurately estimated.

In the parameter estimation system according to the present embodiment, the second parameter estimation device includes: a storage unit configured to store a history of an estimation result estimated by the collective estimation unit; and a determination unit configured to determine whether or not to allow output from the output unit, on the basis of parameters estimated by the collective estimation unit at a first time point and parameters estimated by the collective estimation unit at a second time point which is before the first time point.

The second parameter estimation device includes: a storage unit configured to store a history of an estimation result estimated by the collective estimation unit; and a determination unit configured to determine whether or not to allow output from the output unit, on the basis of parameters estimated by the collective estimation unit at a first time point and parameters estimated by the collective estimation unit at a second time point which is before the first time point.

Due to the above-described configuration, whether or not to allow output of the estimation result of the collective estimation from the output unit is determined on the basis of the history of the estimation result of the collective estimation performed in the past. Therefore, for example, an erroneous estimation result can be prevented from being outputted.

In the parameter estimation system according to the present embodiment, the determination unit determines that the output from the output unit is not allowed when a difference between a parameter of an equivalent circuit of one secondary battery that has been estimated at the first time point and a parameter of the equivalent circuit of the one secondary battery that has been estimated at the second time point is not less than a predetermined threshold.

The determination unit determines that the output from the output unit is not allowed when a difference between a parameter of an equivalent circuit of the secondary battery that has been estimated at the first time point and a parameter of the equivalent circuit of the secondary battery that has been estimated at the second time point is not less than a predetermined threshold. The difference of the parameters may be a difference therebetween or may be a ratio of the parameters. For example, when the value of a parameter of this time has a difference not less than a threshold relative to the value of the previous time, it is considered that the reliability of the collective estimation of this time is low, and thus, the collective estimation result is not outputted. Accordingly, the parameter of the equivalent circuit can be prevented from being updated with erroneous values.

In the parameter estimation system according to the present embodiment, the determination unit determines that the output from the output unit is not allowed when a difference between a parameter of an equivalent circuit of one secondary battery that has been estimated at the first time point and a statistic value of parameters, estimated at the second time point, of equivalent circuits of a plurality of other secondary batteries that are different from the one secondary battery is not less than a predetermined threshold.

The determination unit determines that the output from the output unit is not allowed when the difference between a parameter of the equivalent circuit of the secondary battery that has been estimated at the first time point and a statistic value of the parameters, estimated at the second time point, of equivalent circuits of a plurality of other secondary batteries different from the secondary battery is not less than a predetermined threshold. Here, the plurality of other secondary batteries may be, for example, secondary batteries of the same type (the same model) or being under the same condition (e.g., SOC, temperature, etc.). The statistic value may be an average value or a median. For example, in a case where the value of a parameter of this time has a difference not less than a threshold relative to a statistic value of other secondary batteries, the reliability of the collective estimation of this time is considered to be low, and thus, the collective estimation result is not outputted. Accordingly, the parameters of the equivalent circuit can be prevented from being updated with erroneous values.

In the parameter estimation system according to the present embodiment, the first parameter estimation device uses the sequentially estimated parameters as the parameters of the equivalent circuit without performing update by the update unit, when the determination unit has determined that the output from the output unit is not allowed.

The first parameter estimation device uses the sequentially estimated parameters as the parameters of the equivalent circuit without performing update by the update unit, when the determination unit has determined that the output from the output unit is not allowed. Accordingly, the parameters of the equivalent circuit can be prevented from being updated with erroneous values.

In the parameter estimation system according to the present embodiment, the acquisition unit acquires the current and the voltage of the secondary battery based on the current pattern during charging of the secondary battery performed by a charger.

The acquisition unit acquires the current and the voltage of the secondary battery based on the current pattern during charging of the secondary battery performed by the charger. Accordingly, the parameters of the equivalent circuit can be estimated during charging of the secondary battery.

In the parameter estimation system according to the present embodiment, the second parameter estimation device includes a remaining time acquisition unit configured to acquire a remaining time up to completion of the charging of the secondary battery performed by a charger, and the collective estimation unit collectively estimates the parameters of the equivalent circuit of the secondary battery within the remaining time.

The second parameter estimation device includes a remaining time acquisition unit configured to acquire a remaining time up to completion of the charging of the secondary battery performed by a charger, and the collective estimation unit collectively estimates the parameters of the equivalent circuit of the secondary battery within the remaining time. Accordingly, a calculation condition can be determined such that collective estimation of the parameters of the equivalent circuit ends before completion of the charging of the secondary battery. Thus, highly accurate estimation can be performed within the time before completion of the charging.

In the parameter estimation system according to the present embodiment, the first parameter estimation device includes an identification unit configured to identify an SOC (State Of Charge) of the secondary battery, and starts charging or discharging of the secondary battery based on the current pattern when the SOC identified by the identification unit is at a predetermined value.

The first parameter estimation device includes an identification unit configured to identify the SOC of the secondary battery, and starts charging or discharging of the secondary battery based on the current pattern when the SOC identified by the identification unit is at a predetermined value. For example, when the SOC of the secondary battery has taken a predetermined value (e.g., 50%) during charging of the secondary battery, estimation of the parameters of the equivalent circuit is performed. Accordingly, the condition of the secondary battery when the parameters of the equivalent circuit of the secondary battery are estimated can be made the same, and thus, the parameters can be accurately estimated. In addition, for example, even in a case where a parameter (e.g., a value of the previous time) estimated in the past and a parameter estimated this time are compared with each other, the estimation condition can be made common, and thus, the parameters can be accurately compared with each other.

In the parameter estimation system according to the present embodiment, the current pattern includes a charge current pattern and a discharge current pattern.

The current pattern includes a charge current pattern and a discharge current pattern. Accordingly, a current in both of charging and discharging current patterns is applied to the secondary battery. Thus, change in the SOC of the secondary battery can be inhibited, and the parameters of the equivalent circuit can be accurately estimated.

In the parameter estimation system according to the present embodiment, the first parameter estimation device includes a notification unit configured to notify a charger of a current allowable value of the secondary battery, and a peak value of the current pattern is not greater than the current allowable value.

The first parameter estimation device includes a notification unit configured to notify a charger of a current allowable value of the secondary battery, and a peak value of the current pattern is not greater than the current allowable value. Accordingly, even in a case where the current allowable value is different according to the type or the like of the secondary battery, a current in a current pattern optimum for the secondary battery can be applied.

In the parameter estimation system according to the present embodiment, the first parameter estimation device is capable of selecting communication with respect to a charger, in a priority order of wired communication, short-range wireless communication, and communication using a communication network via the second parameter estimation device.

Communication between the first parameter estimation device and the charger is selectable in the priority order of wired communication, short-range wireless communication, and communication using a communication network via the second parameter estimation device. For example, when both of wired communication and short-range wireless communication are provided, wired communication is preferentially used. Accordingly, an alternative communication means can be used, and thus, estimation of the parameters of the secondary battery can be continued without being interrupted.

In the parameter estimation system according to the present embodiment, when the first parameter estimation device is not provided with a communication function of wired communication and short-range wireless communication with respect to a charger, the first parameter estimation device performs communication with the charger by using a communication network via the second parameter estimation device.

When neither wired communication nor short-range wireless communication is provided between the first parameter estimation device and the charger, communication between the first parameter estimation device and the charger is performed by use of a communication network via the second parameter estimation device. Accordingly, an alternative communication means can be used, and thus, estimation of the parameters of the secondary battery can be continued without being interrupted.

In the parameter estimation system according to the present embodiment, the collection unit further collects a measurement time of the current and the voltage of the secondary battery.

Sensor data such as the current and the voltage of the secondary battery includes measurement time. Accordingly, it is possible to know what time the collected sensor data was measured.

In the parameter estimation system according to the present embodiment, the second parameter estimation device includes a clocking unit, and does not use the current and the voltage measured at the measurement time, when a time difference between the measurement time of the secondary battery and a time of the clocking unit is not less than a predetermined time period.

When the time difference is not less than a predetermined time period, influence of communication delay in the wireless communication is conceivable. Since there is a lag with respect to the measurement time of the collected sensor data, there is a possibility that the parameters of the secondary battery cannot be accurately estimated. Therefore, by not using sensor data that has a lag with respect to the measurement time, it is possible to prevent decrease in estimation accuracy of the parameters of the secondary battery.

### Details of Embodiment of the Present Disclosure

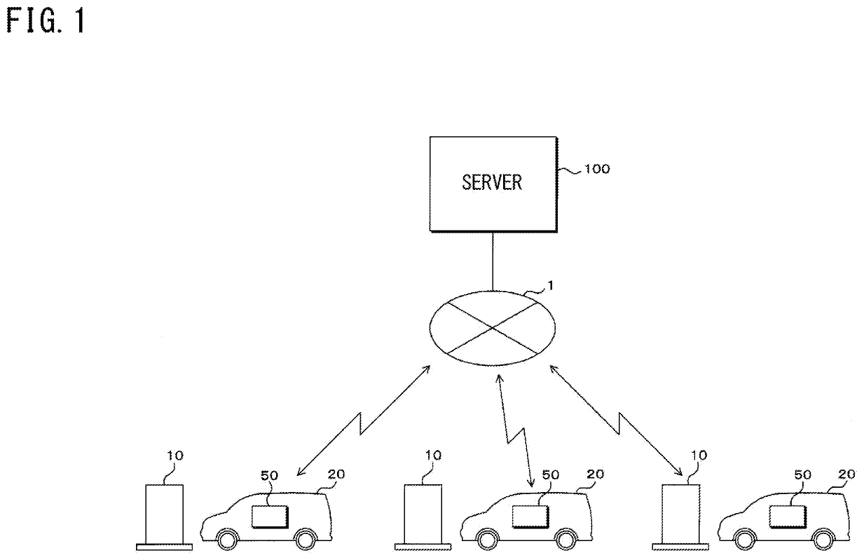

Hereinafter, a parameter estimation system of the present embodiment will be described with reference to the drawings. FIG. 1 is a schematic diagram showing an example of a configuration of a parameter estimation system of the present embodiment. The parameter estimation system includes: a server 100 as a second parameter estimation device; and a battery monitoring device 50 as a first parameter estimation device. The battery monitoring device 50 is installed in a vehicle 20. The vehicle 20 includes, for example, HEVs (Hybrid Electric Vehicles), EVs (Electric Vehicles), and the like. By the vehicle 20 being connected to a charger 10, a later-described secondary battery unit 30 (also referred to as a secondary battery) installed in the vehicle 20 can be charged. The charger 10 is a charging station, for example.

The server 100 can transmit/receive necessary information to/from the battery monitoring device 50 via a communication network 1 such as the Internet. In addition, the server 100 can transmit/receive necessary information to/from the charger 10 via the communication network 1 such as the Internet.

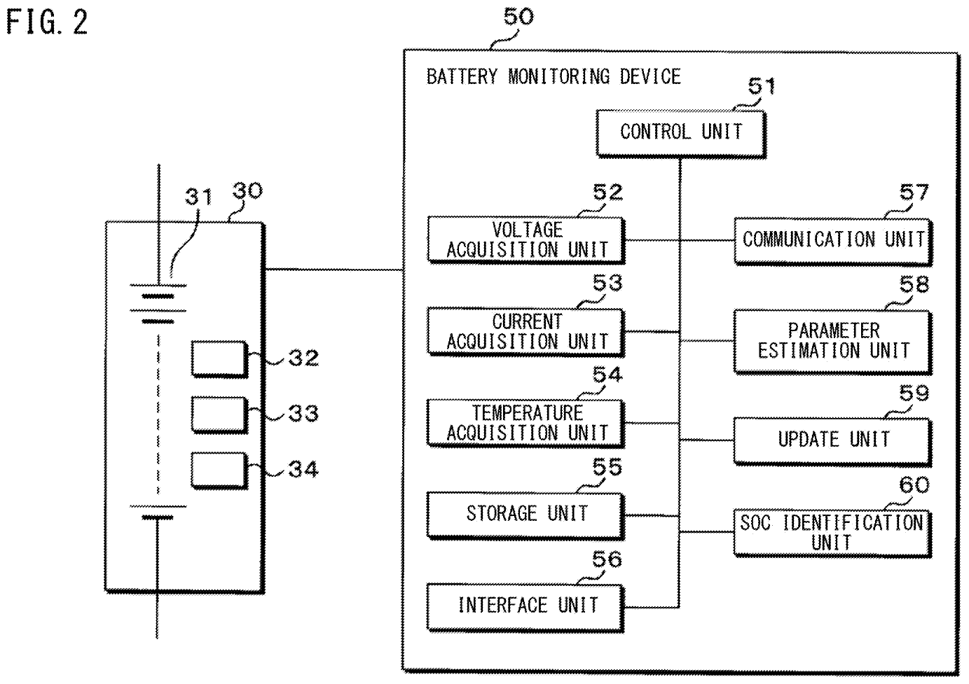

FIG. 2 is a block diagram showing an example of a configuration of a main part of the vehicle 20 having the battery monitoring device 50 installed therein. The secondary battery unit (secondary battery) 30 is a lithium ion battery, for example, and in the secondary battery unit (secondary battery) 30, a plurality of cells (unit cells) 31 are connected in series or series-parallel. The secondary battery unit 30 is provided with a voltage sensor 32, a current sensor 33, and a temperature sensor 34. The voltage sensor 32 detects the voltage of each cell 31 and the voltage between both ends of the secondary battery unit 30, and outputs the detected voltages to the battery monitoring device 50. The current sensor 33 is implemented as, for example, a shunt resistor or a Hall sensor, and detects a charge current and a discharge current of the secondary battery unit 30. The current sensor 33 outputs the detected currents to the battery monitoring device 50. The temperature sensor 34 is implemented as, for example, a thermistor, and detects the temperature of each cell 31. The temperature sensor 34 outputs the detected temperature to the battery monitoring device 50.

The battery monitoring device 50 includes: a control unit 51 which controls the entirety of the device; a voltage acquisition unit 52; a current acquisition unit 53; a temperature acquisition unit 54; a storage unit 55; an interface unit 56; a communication unit 57; a parameter estimation unit 58; an update unit 59; and an SOC identification unit 60.

The control unit 51 can be implemented by a CPU, a ROM, a RAM, and the like. The CPU includes a processor (first processor). Processes performed by the battery monitoring device 50 can be performed by the processor.

The voltage acquisition unit 52 acquires the voltage of each of the plurality of cells 31, and the voltage of the secondary battery unit 30. The current acquisition unit 53 acquires the current (charge current and discharge current) of the secondary battery unit 30. The temperature acquisition unit 54 acquires the temperature of each cell 31.

The storage unit 55 can store the voltage, the current, and the temperature (these are also collectively referred to as “sensor data”) acquired by the voltage acquisition unit 52, the current acquisition unit 53, and the temperature acquisition unit 54. The storage unit 55 can store information received from the server 100.

The interface unit 56 has an interface function for transmitting/receiving information to/from a charging station.

The communication unit 57 has a function of communicating with the server 100 via the communication network 1. The communication unit 57 can transmit sensor data of the secondary battery unit 30 to the server 100 under control of the control unit 51.

The parameter estimation unit 58 has a function as a sequential estimation unit, and sequentially estimates, in each sequential estimation cycle, parameters of an equivalent circuit of the secondary battery unit 30. Details of the sequential estimation will be described later. In the present specification, the cycle of a current pattern is referred to as a pattern cycle, the acquisition cycle of each of the current and the voltage of the secondary battery unit 30 is referred to as a sampling cycle, and the cycle of sequential estimation is referred to as a sequential estimation cycle. The relationship between these cycles will be described later.

When the update unit 59 has acquired, from the server 100, collectively estimated parameters of the equivalent circuit of the secondary battery unit 30, the update unit 59 updates parameters, of the equivalent circuit, that have been estimated (sequentially estimated) by the parameter estimation unit 58, with the collectively estimated parameters of the equivalent circuit. Details of the collective estimation will be described later.

The SOC identification unit 60 has a function as an identification unit, and identifies the SOC (State Of Charge) of the secondary battery unit 30. The SOC (State Of Charge) is a quantity of state representing the ratio of the remaining charge of the secondary battery relative to a full charge capacity. The SOC of the secondary battery unit 30 can be identified as follows, for example. That is, information indicating a correlation between an open circuit voltage (OCV) and the SOC of the secondary battery unit 30 is stored in advance, and then, the OCV of the secondary battery unit 30 is determined, whereby the SOC can be identified. Alternatively, in a case where an initial SOC of the secondary battery unit 30 is known, the current of the secondary battery unit 30 thereafter is integrated, whereby the SOC can be identified.

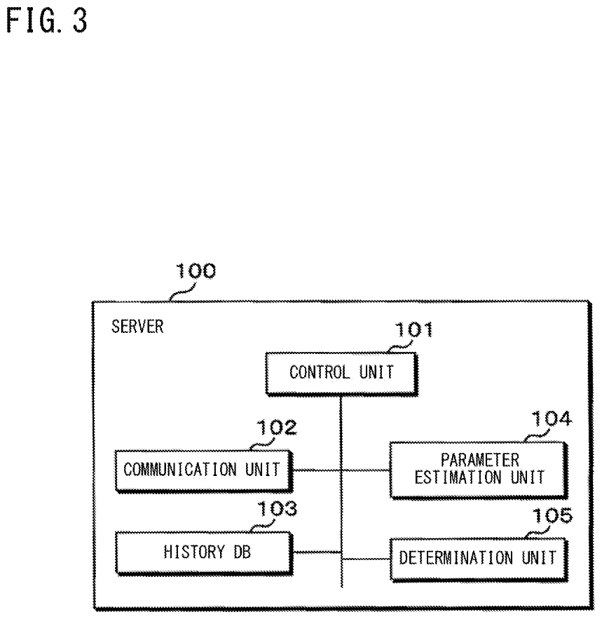

FIG. 3 is a block diagram showing an example of a configuration of the server 100. The server 100 includes: a control unit 101 which controls the entirety of the server 100; a communication unit 102; a history DB 103; a parameter estimation unit 104; and a determination unit 105.

The control unit 101 is implemented by a CPU, a ROM, a RAM, and the like. The CPU includes a processor (second processor). Processes performed by the server 100 can be performed by the processor.

The communication unit 102 has a function of communicating with the battery monitoring device 50 via the communication network 1. In addition, the communication unit 102 has a function of communicating with the charger 10 via the communication network 1.

The communication unit 102 can receive sensor data of the secondary battery unit 30 transmitted by the battery monitoring device 50. That is, the communication unit 102 has a function of a collection unit, and can collect, over a plurality (e.g., 20 times) of pattern cycles, the current and the voltage of the secondary battery unit 30 that have been acquired in the sampling cycle. In a case where the charger 10 transmits sensor data of the secondary battery unit 30, the communication unit 102 can receive the sensor data from the charger 10. For example, when the pattern cycle is 1 second and the sampling cycle is 50 ms, the current and the voltage that can be collected during 20 (20 cycles) pattern cycles correspond to the current and the voltage of 400 times of sampling.

The communication unit 102 has a function as an output unit, and outputs (transmits), to the battery monitoring device 50, parameters of the equivalent circuit of the secondary battery unit 30 that have been collectively estimated by the parameter estimation unit 104.

The parameter estimation unit 104 has a function as a collective estimation unit, and collectively estimates parameters of the equivalent circuit of the secondary battery unit 30 on the basis of the collected current and voltage of the secondary battery unit 30. Details of the collective estimation will be described later.

The history DB 103 has a function as a storage unit and stores the parameters (history of the estimation result) of the equivalent circuit of the secondary battery unit 30 that have been collectively estimated by the parameter estimation unit 104. The estimation result can be separately stored for each of a plurality of different secondary battery units 30 (i.e., for each different vehicle 20).

The determination unit 105 determines whether or not to allow output from the communication unit 102, on the basis of the parameters of the equivalent circuit of the secondary battery unit 30 that have been estimated by the parameter estimation unit 104 at a first time point, and the parameters estimated by the parameter estimation unit 104 at a second time point which is before the first time point.

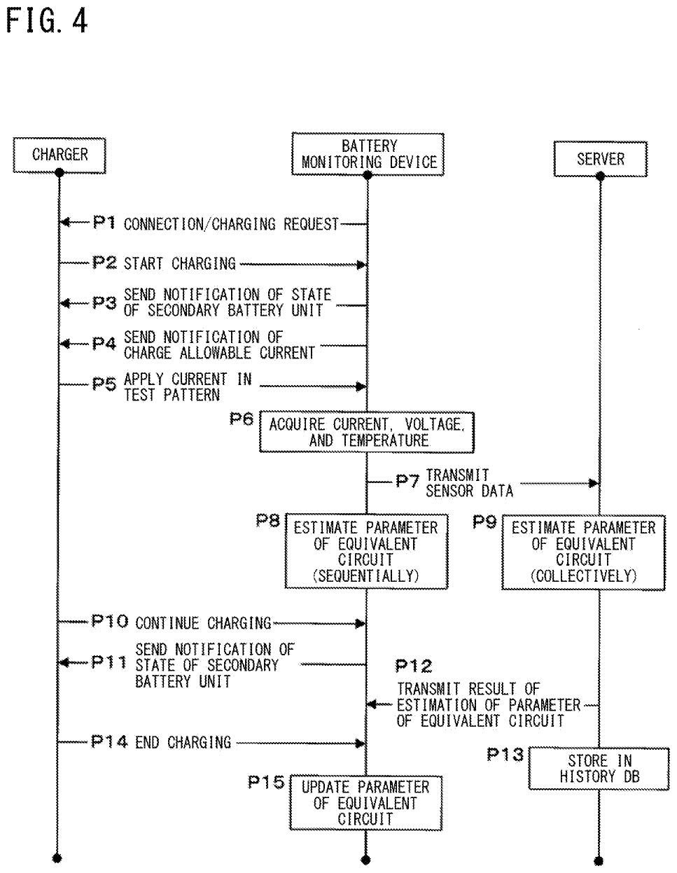

FIG. 4 is a schematic diagram showing an example of a process performed in the parameter estimation system of the present embodiment. In the following, processes P1 to P15 are described.

In P1, the battery monitoring device 50 issues a connection/charging request to the charger 10.

In P2, the charger 10 starts charging of the secondary battery unit 30.

In P3, the battery monitoring device 50 notifies the charger 10 of the state of the secondary battery unit 30. The state of the secondary battery unit 30 includes, for example, SOC, SOH (State Of Health), temperature, etc.

In P4, the battery monitoring device 50 notifies the charger 10 of a charge allowable current. The charge allowable current is a unique allowable current according to the type or the like of the secondary battery unit 30.

In P5, the charger 10 applies a current in a test pattern (also referred to as a current pattern) of the pattern cycle to the secondary battery unit 30.

In P6, the battery monitoring device 50 acquires, in the sampling cycle, the current, the voltage, and the temperature (sensor data) of the secondary battery unit 30 to which the current in the test pattern has been applied.

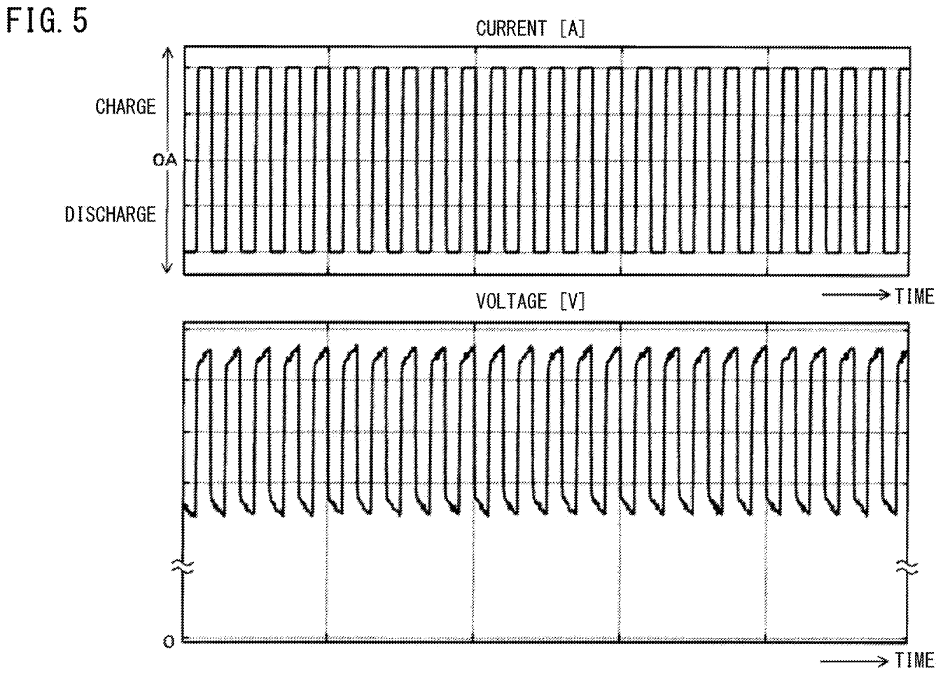

FIG. 5 is a schematic diagram showing an example of the test pattern. In FIG. 5, the upper diagram shows a test pattern (current pattern) and the lower diagram shows a state of the voltage of the secondary battery unit 30 to which the current in the test pattern has been applied. In the test pattern, a charge current and a discharge current are alternately repeated in the pattern cycle. The pattern cycle can be determined as appropriate in accordance with the type or the like of the secondary battery unit 30, and can be about 200 ms, 500 ms, or 1 s, for example.

As shown in FIG. 5, when the test pattern corresponds to charging, the voltage of the secondary battery unit 30 is increased, and when the test pattern corresponds to discharging, the voltage of the secondary battery unit 30 is decreased. In the example shown in FIG. 5, the test pattern includes both of charging and discharging. However, the present invention is not limited thereto. The test pattern may be composed of charging only, or the test pattern may be composed of discharging only.

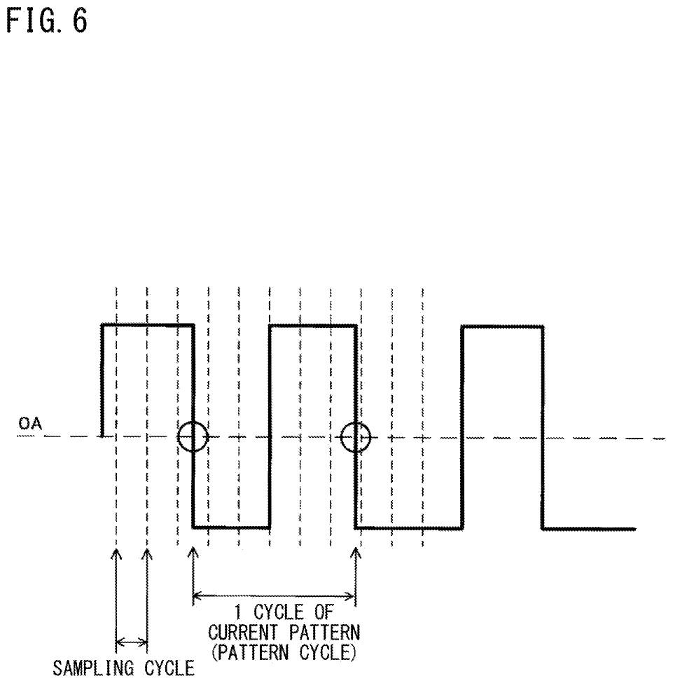

FIG. 6 is a schematic diagram showing an example of a relationship between the pattern cycle and the sampling cycle. As shown in FIG. 6, when the cycle of the current pattern is defined as the pattern cycle, the sampling cycle in which the current and the voltage of the secondary battery unit 30 are acquired is shorter than the pattern cycle. The sequential estimation cycle may be the same as the sampling cycle or may be longer than the sampling cycle (e.g., sampling cycle×2, etc.).

In P7, the battery monitoring device 50 transmits the sensor data of the secondary battery unit 30 to the server 100. The transmission of the sensor data can be performed over a period from the start of the application of the current in the test pattern to the end of the application of the current in the test pattern. That is, the battery monitoring device 50 collects, over a plurality of pattern cycles, the current and the voltage of the secondary battery unit 30 that have been acquired in the sampling cycle in a case where charging or discharging of the secondary battery unit 30 has been performed on the basis of the test pattern of the pattern cycle. Then, the battery monitoring device 50 transmits the collected current and voltage. Accordingly, the server 100 can collect, over a plurality (e.g., 20 times) of pattern cycles, the current and the voltage (sensor data) of the secondary battery unit 30 that have been acquired in the sampling cycle in a case where charging or discharging of the secondary battery unit 30 has been performed on the basis of the test pattern of the pattern cycle. For example, when the pattern cycle is 1 second and the sampling cycle is 50 ms, the current and the voltage that can be collected during 20 (20 cycles) pattern cycles correspond to the current and the voltage of 400 times of sampling.

In P8, the battery monitoring device 50 estimates (performs sequential estimation of) parameters of the equivalent circuit of the secondary battery unit 30. In the following, the sequential estimation is described.

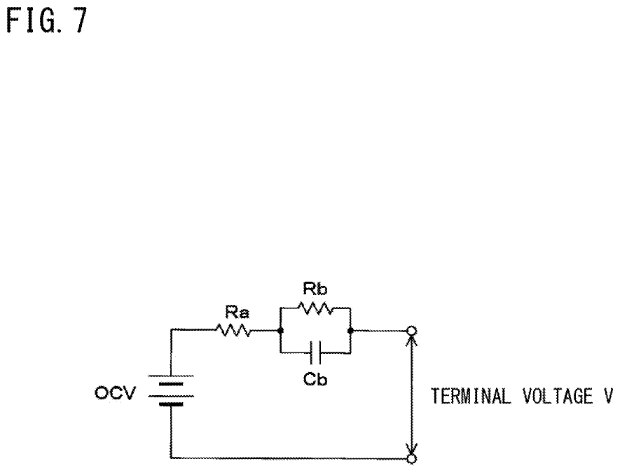

FIG. 7 illustrates an example of an equivalent circuit of the secondary battery unit 30. As shown in FIG. 7, the equivalent circuit (also referred to as an equivalent circuit model) of the secondary battery unit 30 can be represented by a circuit in which a resistor Ra, and a parallel circuit of a resistor Rb and a capacitor Cb are connected in series to a voltage source having the OCV as an electromotive force. In this case, parameters of the equivalent circuit of the secondary battery unit 30 are Ra, Rb, and Cb, the resistor Ra represents the resistance of an electrolyte bulk, the resistor Rb represents an interface charge transfer resistance, and the capacitor Cb represents an electric double layer capacitance. The equivalent circuit of the secondary battery unit 30 is not limited to the example in FIG. 7.

The parameter estimation unit 58 sequentially estimates the parameters of the equivalent circuit of the secondary battery unit 30 on the basis of the current and the voltage acquired in each sampling cycle in a case where a current in the test pattern has been applied to the secondary battery unit 30. That is, an estimation process of the parameters of the equivalent circuit is performed in each sequential estimation cycle. In the following, the estimation process is described.

With respect to the parameters of the equivalent circuit shown as an example in FIG. 7, it is known that the following approximate equations are established.

V(k)=b0·I(k)+b1·I(k−1)−a1·V(k−1)+(1+a1)·OCV (1)

b₀=Ra (2)

b1=Ts·Ra/(Rb·Cb)+Ts/Cb−Ra (3)

a1=Ts/(Rb·Cb)−1 (4)

Here, V(k) is the voltage of the secondary battery unit 30 in a sampling cycle k, I(k) is the current of the secondary battery unit 30 in the sampling cycle k, and Ts is the sequential estimation cycle and, in this example, is equal to the sampling cycle of the voltage and the current.

When the parameters Ra, Rb, and Cb of the equivalent circuit are back-calculated from the above equations (2) to (4), the following equations (5) to (7) are established.

Ra=b0 (5)

Rb=(b1−a1·b0)/(1+a1) (6)

Cb=Ts/(b1−a1·b0) (7)

In the present embodiment, the recursive least squares method is applied to equation (1), to determine the coefficients b0, b1, and a1, and the determined coefficients are substituted into equations (5) to (7), to estimate the parameters Ra, Rb, and Cb. It is assumed that the OCV is constant while each parameter is estimated once. The estimated parameters may be corrected in accordance with the temperature acquired by the temperature acquisition unit 54.

It is also possible to calculate the parameters Ra, Rb, and Cb by using a Kalman filter. Specifically, an observation vector when an input signal represented by a voltage and a current is given to the secondary battery unit 30, and a state vector when the same input signal as above is given to the equivalent circuit model of the secondary battery unit 30 are compared with each other. The error between these vectors is multiplied by the Kalman gain, and the resultant value is fed back to the equivalent circuit model, to repeat correction of the equivalent circuit model such that the error between both vectors is minimized. Accordingly, the parameters are estimated.

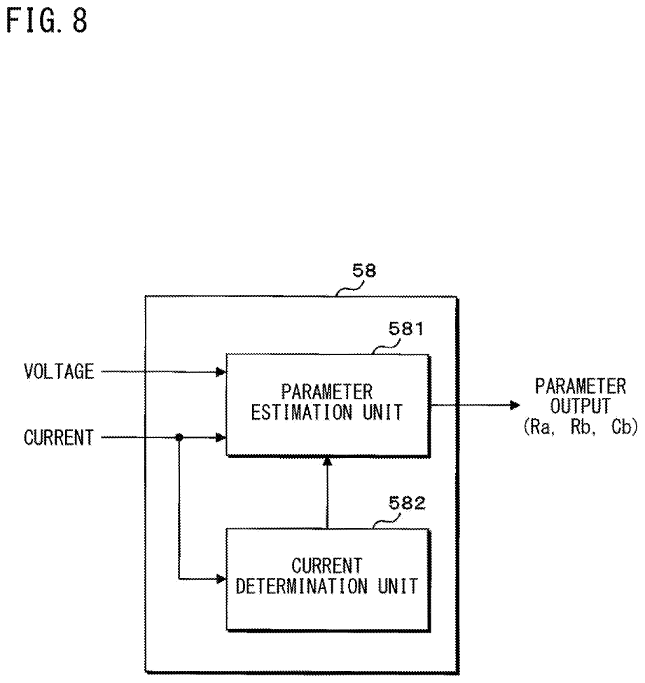

FIG. 8 is a block diagram showing an example of a configuration of the parameter estimation unit 58. The parameter estimation unit 58 includes: a parameter estimation unit 581 which sequentially estimates the parameters of the equivalent circuit of the secondary battery unit 30; and a current determination unit 582. The parameter estimation unit 581 performs calculation of the sequential estimation in each sequential estimation cycle. The current determination unit 582 prohibits estimation of the parameters performed by the parameter estimation unit 581 when the current of the secondary battery unit 30 is smaller than a predetermined current threshold, and when a change amount of the current is smaller than a predetermined change amount threshold. When estimation of the parameters has been prohibited by the current determination unit 582, the parameter estimation unit 581 can output the parameters estimated in the previous time, without being updated. Accordingly, decrease in the accuracy of the estimation result of the parameters of the equivalent circuit can be prevented.

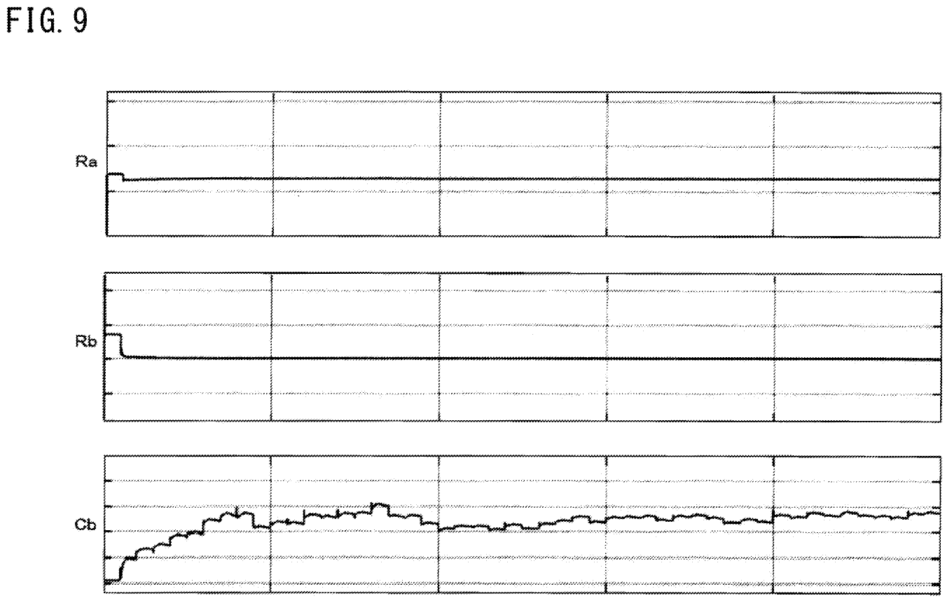

FIG. 9 shows an example of transition of the estimation result of the parameters of the equivalent circuit obtained through sequential estimation. In FIG. 9, the horizontal axis represents time. FIG. 9 shows transition of estimated values of the parameters Ra, Rb, and Cb when the sequential estimation is repeated in the sequential estimation cycle. The parameters Ra, Rb, and Cb each converge to a constant value with a lapse of time, through repetition of the sequential estimation. The constant value after the lapse of a predetermined time period (e.g., 10 seconds, 20 seconds, or 30 seconds) can be used as an estimation result.

In P9, the server 100 estimates (performs collective estimation of) the parameters of the equivalent circuit of the secondary battery unit 30. In the following, the collective estimation is described.

The parameter estimation unit 104 collectively estimates the parameters of the equivalent circuit of the secondary battery unit 30 on the basis of the collected current and voltage of the secondary battery unit 30.

In a case where the parameters of the equivalent circuit of the secondary battery unit 30 are those shown in FIG. 7, in the collective estimation, fitting of Ra, Rb, and Cb is performed in equation (8) such that the sum of squares of the remainder between the calculated value of voltage V(k) when the current value I(k) in all of a plurality of sampling cycles has been inputted and the actually measured value (voltage value acquired in the sampling cycle) of voltage V(k) is minimized.

$$\begin{matrix}[ Math 1 ] & \\ V ( k ) = Ra \times 1 ( k ) + \frac{( Rb \cdot Ts ) / ( Cb \cdot Rb + Ts )}{1 - ( Cb \cdot Rb ) / ( Cb \cdot Rb + Ts ) {z}^{- 1}} \times 1 ( k ) & ( 8 )\end{matrix}$$

In equation (8), Ts is the sampling cycle. z is a representation using a transfer function of z-transform.

When fitting is repeatedly performed using the same data, the sum of squares of the remainder being an evaluation function becomes small, and the solution converges. That is, by repeatedly performing a process of determining an optimum solution, it is possible to obtain an estimated value having a higher accuracy than that by the sequential estimation.

The sequential estimation by the parameter estimation unit 58 is calculation performed in each sequential cycle. In contrast, in the collective estimation by the parameter estimation unit 104, collective estimation is performed by using all the data of the plurality of pattern cycles, and thus, the amount of information is increased, whereby estimation accuracy can be increased.

In P10, the charger 10 is continually performing charging.

In P11, the battery monitoring device 50 notifies the charger 10 of the state of the secondary battery unit 30. The notification in P11 can include, for example, that the SOC of the secondary battery unit 30 has reached an upper limit value (charging has been completed).

In P12, in the server 100, the collective estimation by the parameter estimation unit 104 has ended, and the server 100 transmits an estimation result of the parameters of the equivalent circuit to the battery monitoring device 50.

In P13, the server 100 stores the estimation result into the history DB 103.

In P14, the charger 10 ends charging.

In P15, the battery monitoring device 50 updates the parameters of the equivalent circuit. That is, when the update unit 59 has acquired collectively estimated parameters of the equivalent circuit from the server 100, the update unit 59 updates the parameters of the equivalent circuit that have been sequentially estimated by the parameter estimation unit 58, with the collectively estimated parameters of the equivalent circuit.

Accordingly, the parameters of the equivalent circuit estimated through the sequential estimation are updated with the collectively estimated parameters having a higher accuracy. Therefore, the parameters of the equivalent circuit can be more accurately estimated.

The determination unit 105 can determine whether or not to transmit, to the battery monitoring device 50, an estimation result at the first time point, on the basis of the parameters of the equivalent circuit that have been estimated by the parameter estimation unit 104 at the first time point (e.g., this time), and the parameters of the equivalent circuit that have been estimated by the parameter estimation unit 104 at the second time point (e.g., previous time) which is before the first time point.

Due to the above-described configuration, whether or not to allow transmission (output) of the estimation result of the parameters of the equivalent circuit that have been estimated by the parameter estimation unit 104 is determined on the basis of the history of the estimation result of the collective estimation performed in the past. Therefore, for example, an erroneous estimation result can be prevented from being transmitted to the battery monitoring device 50.

When the difference between a parameter of the equivalent circuit of the secondary battery unit 30 that has been estimated at the first time point and a parameter of the equivalent circuit of the secondary battery unit 30 that has been estimated at the second time point is not less than a predetermined threshold, the determination unit 105 can determine that the estimation result at the first time point is not allowed to be transmitted to the battery monitoring device 50.

The difference of the parameters may be a difference therebetween or may be a ratio of the parameters. For example, when the value of a parameter of this time has a difference not less than a threshold relative to the value of the previous time, it is considered that the reliability of the collective estimation of this time is low, and thus, the collective estimation result is not outputted. Accordingly, in the battery monitoring device 50, the parameters of the equivalent circuit are prevented from being updated with erroneous values.

When the difference between a parameter of the equivalent circuit of the secondary battery unit 30 that has been estimated at the first time point and a statistic value of the parameters, estimated at the second time point, of equivalent circuits of a plurality of other secondary battery units different from the secondary battery unit 30 is not less than a predetermined threshold, the determination unit 105 can determine that the estimation result at the first time point is not allowed to be transmitted to the battery monitoring device 50. Here, the plurality of other secondary battery units may be, for example, secondary battery units of the same type (the same model) or being under the same condition (e.g., SOC, temperature, etc.).

The statistic value may be an average value or a median. For example, in a case where the value of a parameter of this time has a difference not less than a threshold relative to a statistic value of other secondary battery units, the reliability of the collective estimation of this time is considered to be low, and thus, the collective estimation result is not outputted. Accordingly, in the battery monitoring device 50, the parameters of the equivalent circuit is prevented from being updated with erroneous values.

When the determination unit 105 of the server 100 has determined that the estimation result is not allowed to be transmitted to the battery monitoring device 50, the battery monitoring device 50 uses the sequentially estimated parameters as the parameter of the equivalent circuit, without performing update by the update unit 59. Accordingly, the parameters of the equivalent circuit can be prevented from being updated with erroneous values.

The battery monitoring device 50 acquires the current and the voltage of the secondary battery unit 30 based on the test pattern of the pattern cycle during charging of the secondary battery unit 30 performed by the charger 10. Accordingly, the parameters of the equivalent circuit can be estimated during charging of the secondary battery unit 30.

The charger 10 can transmit, to the server 100, a remaining time up to completion of charging of the secondary battery unit 30. The battery monitoring device 50 may transmit the remaining time to the server 100. The communication unit 102 of the server 100 has a function as a remaining time acquisition unit which acquires the remaining time. The parameter estimation unit 104 collectively estimates the parameters of the equivalent circuit of the secondary battery unit 30 within the remaining time. Accordingly, a calculation condition can be determined such that collective estimation of the parameters of the equivalent circuit ends before completion of the charging of the secondary battery unit 30. Thus, highly accurate estimation can be performed within the time before completion of the charging.

The SOC identification unit 60 can identify the SOC of the secondary battery unit 30 during charging. The control unit 51 can output, to the charger 10, an instruction of starting application of a current in the test pattern to the charger 10, when the SOC identified by the SOC identification unit 60 is at a predetermined value. Accordingly, charging or discharging, of the secondary battery unit 30, based on the test pattern of the pattern cycle can be started.

For example, when the SOC of the secondary battery unit 30 has taken a predetermined value (e.g., 50%) during charging of the secondary battery unit 30, estimation of the parameters of the equivalent circuit is performed. Accordingly, the condition of the secondary battery unit 30 when the parameters of the equivalent circuit of the secondary battery unit 30 are estimated can be made the same, and thus, the parameters can be accurately estimated. In addition, for example, even in a case where a parameter (e.g., a value of the previous time) estimated in the past and a parameter estimated this time are compared with each other, the estimation condition can be made common, and thus, the parameters can be accurately compared with each other.

Application of a current in the test pattern may be started before the SOC identified by the SOC identification unit 60 takes a predetermined value, and when the SOC of the secondary battery unit 30 has taken the predetermined value, the sequential estimation by the parameter estimation unit 58 may be started.

The test pattern of the pattern cycle may be composed only of a charge current pattern or a discharge current pattern. Alternatively, as described above, the test pattern of the pattern cycle may include both of a charge current pattern and a discharge current pattern. Accordingly, a current in both of the charging and discharging patterns is applied to the secondary battery unit 30. Thus, change in the SOC of the secondary battery unit 30 can be inhibited, and the parameters of the equivalent circuit can be accurately estimated.

The interface unit 56 has a function as a notification unit which notifies the charger 10 of a current allowable value of the secondary battery unit 30. The charger 10 can set the peak value of the test pattern to be not greater than the current allowable value. More specifically, the peak value of the test pattern can be set to the current allowable value. Accordingly, the peak value of the current can be a large value within an allowable range, errors of measurement can be ignored, and estimation accuracy of parameters of the equivalent circuit can be increased. Even in a case where the current allowable value is different according to the type or the like of the secondary battery unit, a current in a current pattern optimum for the secondary battery unit can be applied.

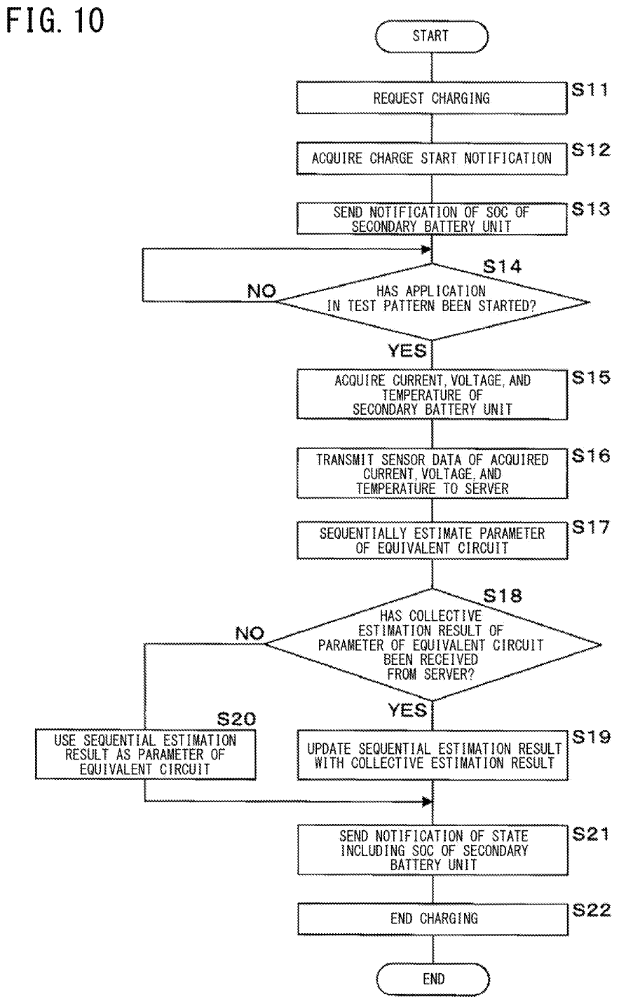

FIG. 10 is a flow chart showing an example of a procedure of a process performed by the battery monitoring device 50. For convenience, the following is described assuming that the subject that performs the process is the control unit 51. The control unit 51 issues a charging request to the charger 10 (S11), and when charging is started (or before charging is started), the control unit 51 acquires a charge start notification from the charger 10 (S12). Accordingly, the secondary battery unit 30 is charged.

The control unit 51 sends a notification that the SOC of the secondary battery unit 30 has taken a predetermined value (e.g., 50%) (S13). The control unit 51 determines whether or not application of a current in the test pattern has been started from the charger 10 to the secondary battery unit 30 (S14), and when the application has not been started (NO in S14), the control unit 51 continues the process of step S14.

When the application in the test pattern has been started (YES in S14), the control unit 51 acquires, in each sampling cycle, a current, a voltage, and a temperature of the secondary battery unit 30 (S15), and transmits sensor data of the acquired current, voltage, and temperature to the server 100 (S16).

The control unit 51 sequentially estimates the parameters of the equivalent circuit of the secondary battery unit 30, in each sequential estimation cycle (S17). The process of the sequential estimation is performed in each sequential estimation cycle, repeatedly. The control unit 51 determines whether or not a collective estimation result of the parameters of the equivalent circuit of the secondary battery unit 30 has been received from the server 100 (S18). The process of the collective estimation is an estimation process in which, when sensor data per sampling cycle is defined as one piece of sampling data, pieces of sampling data corresponding to a plurality of (e.g., 20, 30, etc.) pattern cycles are collectively used.

When having received the collective estimation result (YES in S18), the control unit 51 updates the sequential estimation result with the collective estimation result (S19), and performs the process of step S21 described later. When the collective estimation result has not been received (NO in S18), or when an instruction to prohibit update of the estimation result has been received from the server 100, the control unit 51 uses the sequential estimation result as the parameters of the equivalent circuit (S20).

The control unit 51 notifies the charger 10 of the state including the SOC of the secondary battery unit 30 (S21). Here, the notification can include, for example, that the SOC of the secondary battery unit 30 has reached an upper limit value (i.e., has been fully charged). The control unit 51 ends the charging (S22) and ends the process.

The battery monitoring device 50 of the present embodiment can also be realized by using a general-purpose computer including a CPU (processor), a RAM (memory), and the like. That is, a storage medium having stored therein a computer program defining the procedure of the processes as shown in FIG. 10 is read by a storage medium reading device provided in a computer, the read computer program is loaded to the RAM (memory), and the computer program is executed by the CPU (processor), whereby the battery monitoring device 50 can be realized in the computer.

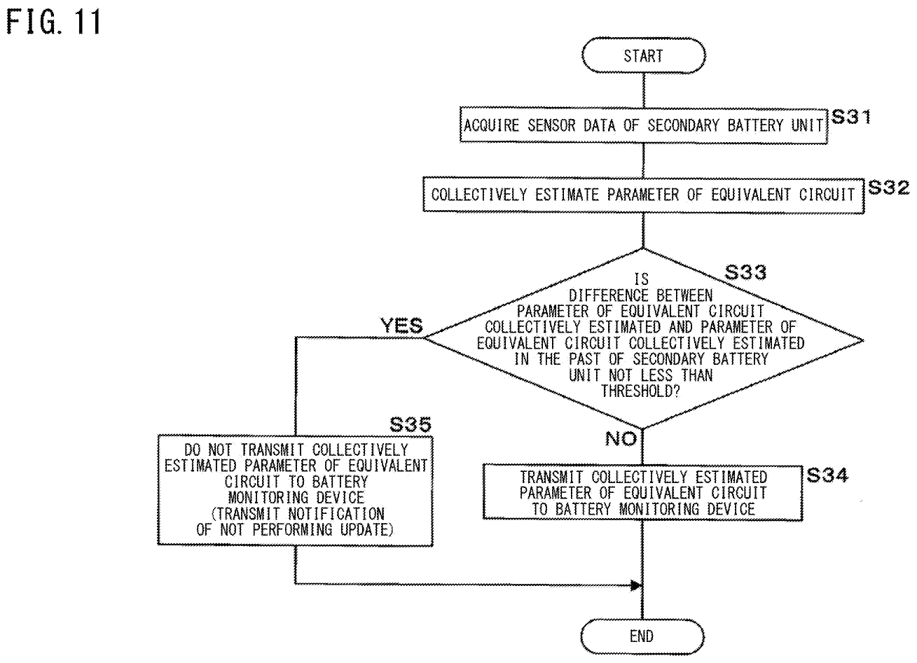

FIG. 11 is a flow chart showing an example of a procedure of a process performed by the server 100. For convenience, the following is described assuming that the subject that performs the process is the control unit 101. The control unit 101 acquires sensor data of the secondary battery unit 30 (S31), and collectively estimates the parameters of the equivalent circuit of the secondary battery unit 30 (S32). The control unit 101 determines whether or not the difference between the parameters of the equivalent circuit of the secondary battery unit 30 collectively estimated in step S32 and the parameters of the equivalent circuit collectively estimated in the past of the secondary battery unit 30 is not less than a threshold (S33). Here, the equivalent circuit for which collective estimation was performed in the past may be, for example, an equivalent circuit of a secondary battery unit of the same type (the same model), or an equivalent circuit for which estimation was performed under the same condition (e.g., SOC, temperature, etc.).

When the difference is less than the threshold (NO in S33), the control unit 101 transmits, to the battery monitoring device 50, the parameters of the equivalent circuit of the secondary battery unit 30 that have been collectively estimated in step S32 (S34), and ends the process. The parameters of the equivalent circuit of the secondary battery unit 30 that have been collectively estimated in step S32 can be stored in the history DB 103.

When the difference is not less than the threshold (YES in S33), the control unit 101 does not transmit, to the battery monitoring device 50, the parameters of the equivalent circuit of the secondary battery unit 30 that have been collectively estimated in step S32 (S35). Alternatively, the control unit 101 may transmit, to the battery monitoring device 50, a notification that the estimation result is not to be updated. The control unit 101 ends the process.

The server 100 of the present embodiment can also be realized by using a general-purpose computer including a CPU (processor), a RAM (memory), and the like. That is, a storage medium having stored therein a computer program defining the procedure of the processes as shown in FIG. 11 is read by a storage medium reading device provided in a computer, the read computer program is loaded to the RAM (memory), and the computer program is executed by the CPU (processor), whereby the server 100 can be realized in the computer.

Next, a communication means between the charger 10 and the battery monitoring device 50 is described.

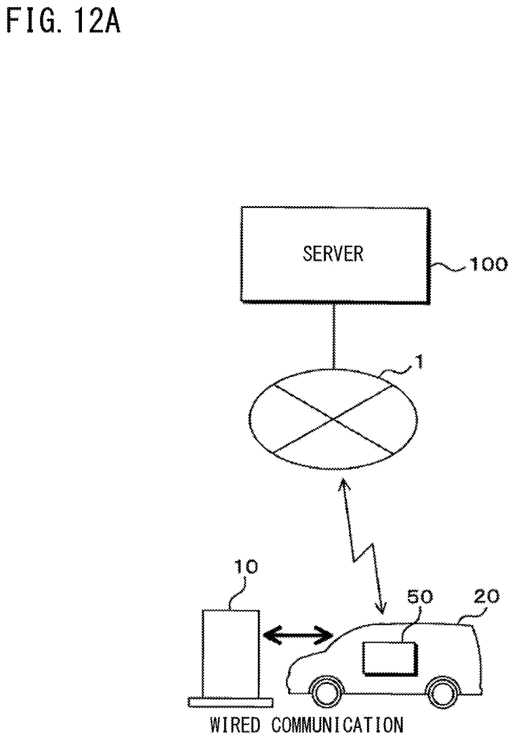

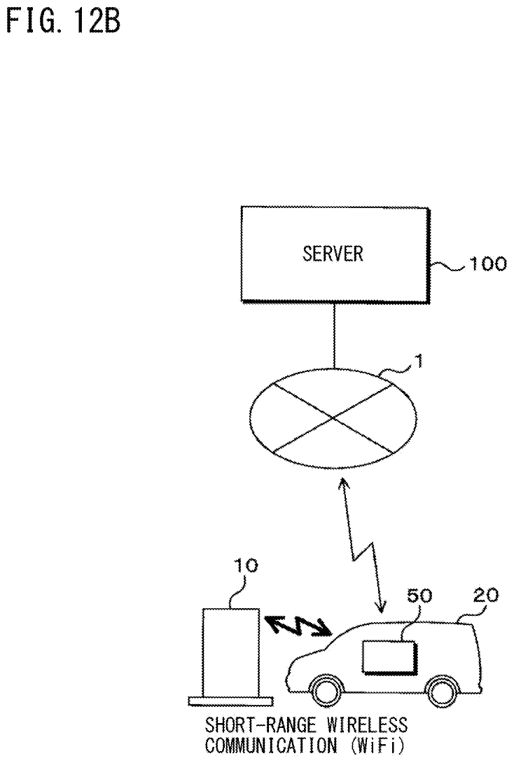

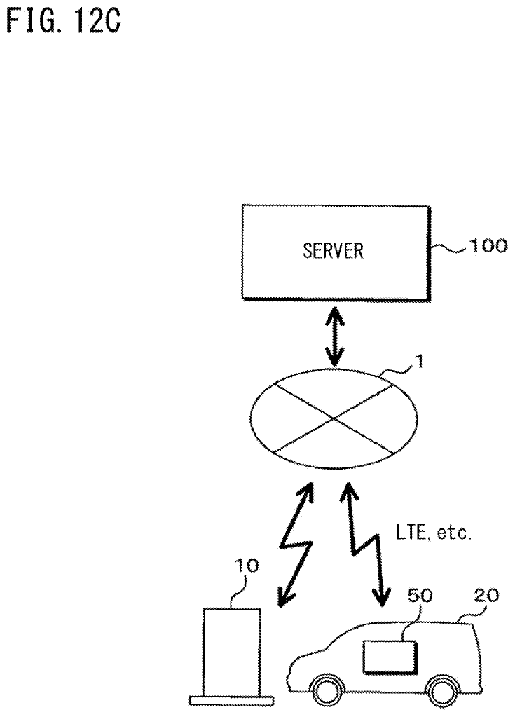

FIG. 12A, FIG. 12B, and FIG. 12C are schematic diagrams respectively showing a first example, a second example, and a third example of communication means between the charger 10 and the battery monitoring device 50. The first example shown in FIG. 12A is a case where wired communication such as PLC (Power Line Communication) communication or CAN (Controller Area Network) communication is used. The second example shown in FIG. 12B is a case where wireless communication such as short-range wireless communication (e.g., WiFi (registered trademark)) is used. The third example shown in FIG. 12C is a case where communication is performed via the server 100 by using the communication network 1 (e.g., LTE (Long Term Evolution)) or the like.

In a case where the battery monitoring device 50 is provided with communication means of the first example through the third example described above, a communication means can be selected in a priority order of, for example, the PLC communication or CAN communication, the short-range wireless communication, and the communication via the server 100. In a case where the battery monitoring device 50 is not provided with any of the communication means of the PLC communication, the CAN communication, and the short-range wireless communication, communication can be performed via the server 100. As described above, through provision of a plurality of communication means, even when a situation where one communication means cannot be used has occurred, if an alternative communication means is used, estimation of the parameters of the secondary battery can be continued without being interrupted.

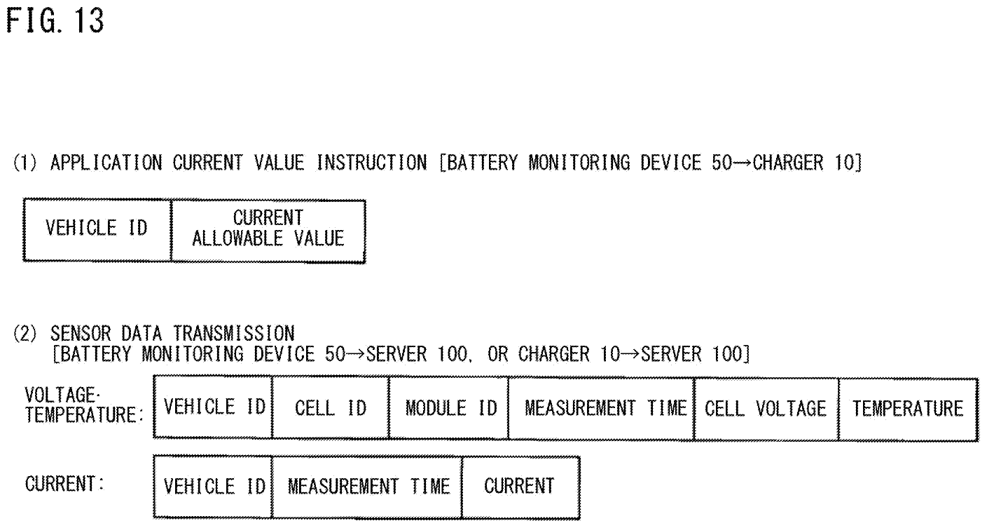

FIG. 13 is a schematic diagram showing an example of a configuration of a wireless communication frame. An application current value instruction shown in FIG. 13 is issued from the battery monitoring device 50 to the charger 10 when the charger 10 is to apply, to the secondary battery unit 30, a charging or discharging current in a test pattern. The instruction content is an application current within a current limiting range. The application current value instruction includes data related to a vehicle ID and a current allowable value.

When a current in the test pattern has been applied to the secondary battery unit 30, sensor data is transmitted to the server 100. The sensor data may be transmitted from the battery monitoring device 50 to the server 100, or may be transmitted from the charger 10 to the server 100. In a case where the sensor data is voltage or temperature, the sensor data transmission includes data related to vehicle ID, cell ID, module ID, measurement time, cell voltage, and temperature. In a case where the sensor data is current, the sensor data transmission includes data related to vehicle ID, measurement time, and current.

When a communication delay occurs in a case of short-range wireless communication (the second example) or communication via the server 100 (the third example), a time lag of the sensor data occurs, which may result in decreased estimation accuracy of the parameters of the secondary battery. As described above, the sensor data transmission includes measurement time. Thus, the server 100 may include a timer (clocking unit), and if the time difference between the measurement time and the time of the reception of the sensor data is within a predetermined time period, the server 100 can determine that there is no influence of the communication delay in the wireless communication, and perform estimation of the parameters of the secondary battery. When the time difference between the measurement time and the time of the reception of the sensor data is not within the predetermined time period, the server 100 determines that there is an influence of the communication delay in the wireless communication, and, for example, does not use the received sensor data. Accordingly, decrease in estimation accuracy of the parameters of the secondary battery can be prevented.

In the present embodiment, the charger 10 generates a test pattern and applies a current in the test pattern to the secondary battery unit 30. However, the present disclosure is not limited thereto. The battery monitoring device 50 may generate a test pattern and apply a current in the test pattern to the secondary battery unit 30.

In the present embodiment, the battery monitoring device 50 sequentially estimates the parameters of the equivalent circuit of the secondary battery unit 30. However, the present disclosure is not limited thereto. The charger 10 may sequentially estimate the parameters of the equivalent circuit of the secondary battery unit 30.

In the present embodiment, the battery monitoring device 50 transmits sensor data to the server 100. However, the present disclosure is not limited thereto. The charger 10 may transmit sensor data to the server 100.

In the present embodiment, a current in the test pattern is applied during charging of the secondary battery unit 30 performed by the charger 10, to estimate the parameters of the equivalent circuit. However, the present disclosure is not limited thereto. For example, a current in the test pattern may be applied, while the vehicle 20 is traveling, during charging of the secondary battery unit 30 performed by a charger in the vehicle 20, to estimate the parameter of the equivalent circuit.

In the present embodiment, communication is directly performed between the battery monitoring device 50 and the server 100. However, the present disclosure is not limited thereto. The communication between the battery monitoring device 50 and the server 100 may be performed via the charger 10.

In the present embodiment, the peak value (amplitude) of the test pattern is a constant value. However, the present disclosure is not limited thereto. The amplitude of the test pattern may be varied with a lapse of time. When parameters of the equivalent circuit estimated by use of currents and voltages according to a test pattern having different amplitudes each take the same value (or similar values), it is considered that the parameter value is converging.

In the present embodiment, the parameters of the equivalent circuit that have been sequentially estimated by the battery monitoring device 50 may be transmitted to the server 100, and the server 100 may compare the received parameters of the equivalent circuit with a statistic value of other secondary battery units or with past history data, and determine whether or not to update the parameters of the equivalent circuit that have been sequentially estimated.

In the present embodiment, deterioration of the secondary battery unit can be detected on the basis of the estimated values of the parameters of the equivalent circuit. For example, deterioration of the secondary battery unit can be detected or a deterioration degree thereof can be determined, on the basis of an increase amount of the resistance Ra among the estimated parameters.

The disclosed embodiment is illustrative in all aspects and should not be recognized as being restrictive. The scope of the present disclosure is defined by the scope of the claims rather than the above description, and is intended to include meaning equivalent to the scope of the claims and all modifications within the scope.

The above description includes the features in the additional note below.

### (Additional Note)

A parameter estimation system comprising a first parameter estimation device and a second parameter estimation device which estimate parameters of an equivalent circuit of a secondary battery,

the first parameter estimation device including a first processor,

the processor being configured to
acquire a current and a voltage of the secondary battery when charging or discharging of the secondary battery has been performed on the basis of a current pattern, and
sequentially estimate the parameters of the equivalent circuit of the secondary battery on the basis of the acquired current and voltage,

the second parameter estimation device including a second processor,

the second processor being configured to
collect the current and the voltage of the secondary battery when charging or discharging of the secondary battery has been performed on the basis of the current pattern,
collectively estimate the parameters of the equivalent circuit of the secondary battery on the basis of the collected current and voltage, and
output the collectively estimated parameters to the first parameter estimation device,

the first processor being configured to
update, when the collectively estimated parameters have been acquired from the second parameter estimation device, the sequentially estimated parameters with the collectively estimated parameters.

### REFERENCE SIGNS LIST

1 communication network
10 charger
20 vehicle
30 secondary battery unit
31 cell
32 voltage sensor
33 current sensor
34 temperature sensor
50 battery monitoring device
51 control unit
52 voltage acquisition unit
53 current acquisition unit
54 temperature acquisition unit
55 storage unit
56 interface unit
57 communication unit
58 parameter estimation unit
581 parameter estimation unit
582 current determination unit
59 update unit
60 SOC identification unit
100 server
101 control unit
102 communication unit
103 history DB
104 parameter estimation unit
105 determination unit

1. A parameter estimation system comprising a first parameter estimation device and a second parameter estimation device which estimate parameters of an equivalent circuit of a secondary battery,
the first parameter estimation device including
an acquisition unit configured to acquire a current and a voltage of the secondary battery when charging or discharging of the secondary battery has been performed on the basis of a current pattern, and
a sequential estimation unit configured to sequentially estimate the parameters of the equivalent circuit of the secondary battery on the basis of the current and the voltage acquired by the acquisition unit,
the second parameter estimation device including
a collection unit configured to collect the current and the voltage of the secondary battery when charging or discharging of the secondary battery has been performed on the basis of the current pattern,
a collective estimation unit configured to collectively estimate the parameters of the equivalent circuit of the secondary battery on the basis of the current and the voltage collected by the collection unit, and
an output unit configured to output the parameters estimated by the collective estimation unit to the first parameter estimation device,
the first parameter estimation device further including
an update unit configured to update, when the collectively estimated parameters have been acquired from the second parameter estimation device, the sequentially estimated parameters with the collectively estimated parameters.

2. The parameter estimation system according to claim 1, wherein
the second parameter estimation device includes
a storage unit configured to store a history of an estimation result estimated by the collective estimation unit, and
a determination unit configured to determine whether or not to allow output from the output unit, on the basis of parameters estimated by the collective estimation unit at a first time point and parameters estimated by the collective estimation unit at a second time point which is before the first time point.

3. The parameter estimation system according to claim 2, wherein
the determination unit determines that the output from the output unit is not allowed when a difference between a parameter of an equivalent circuit of one secondary battery that has been estimated at the first time point and a parameter of the equivalent circuit of the one secondary battery that has been estimated at the second time point is not less than a predetermined threshold.

4. The parameter estimation system according to claim 2, wherein
the determination unit determines that the output from the output unit is not allowed when a difference between a parameter of an equivalent circuit of one secondary battery that has been estimated at the first time point and a statistic value of parameters, estimated at the second time point, of equivalent circuits of a plurality of other secondary batteries that are different from the one secondary battery is not less than a predetermined threshold.

5. The parameter estimation system according to claim 2, wherein
the first parameter estimation device uses the sequentially estimated parameters as the parameters of the equivalent circuit without performing update by the update unit, when the determination unit has determined that the output from the output unit is not allowed.

6. The parameter estimation system according to claim 1, wherein
the acquisition unit acquires the current and the voltage of the secondary battery based on the current pattern during charging of the secondary battery performed by a charger.

7. The parameter estimation system according to claim 1, wherein
the second parameter estimation device includes a remaining time acquisition unit configured to acquire a remaining time up to completion of the charging of the secondary battery performed by a charger, and
the collective estimation unit collectively estimates the parameters of the equivalent circuit of the secondary battery within the remaining time.

8. The parameter estimation system according to claim 1, wherein
the first parameter estimation device
includes an identification unit configured to identify an SOC (State Of Charge) of the secondary battery, and
starts charging or discharging of the secondary battery based on the current pattern when the SOC identified by the identification unit is at a predetermined value.

9. The parameter estimation system according to claim 1, wherein
the current pattern includes a charge current pattern and a discharge current pattern.

10. The parameter estimation system according to claim 1, wherein
the first parameter estimation device includes a notification unit configured to notify a charger of a current allowable value of the secondary battery, and
a peak value of the current pattern is not greater than the current allowable value.

11. The parameter estimation system according to claim 1, wherein
the first parameter estimation device is capable of selecting communication with respect to a charger, in a priority order of wired communication, short-range wireless communication, and communication using a communication network via the second parameter estimation device.

12. The parameter estimation system according to claim 1, wherein
when the first parameter estimation device is not provided with a communication function of wired communication and short-range wireless communication with respect to a charger, the first parameter estimation device performs communication with the charger by using a communication network via the second parameter estimation device.

13. The parameter estimation system according to claim 1, wherein
the collection unit further collects a measurement time of the current and the voltage of the secondary battery.

14. The parameter estimation system according to claim 13, wherein
the second parameter estimation device
includes a clocking unit, and
does not use the current and the voltage measured at the measurement time, when a time difference between the measurement time of the secondary battery and a time of the clocking unit is not less than a predetermined time period.

15. A parameter estimation device configured to estimate parameters of an equivalent circuit of a secondary battery, the parameter estimation device comprising:
an acquisition unit configured to acquire a current and a voltage of the secondary battery when charging or discharging of the secondary battery has been performed on the basis of a current pattern;
a sequential estimation unit configured to sequentially estimate the parameters of the equivalent circuit of the secondary battery on the basis of the current and the voltage acquired by the acquisition unit; and
an update unit configured to update, when collectively estimated parameters of the equivalent circuit of the secondary battery that are based on the current and the voltage of the secondary battery have been acquired in a case where charging or discharging of the secondary battery has been performed on the basis of the current pattern, the sequentially estimated parameters with the collectively estimated parameters.

16. A vehicle comprising the parameter estimation device according to claim 15.

17. A parameter estimation device configured to estimate parameters of an equivalent circuit of a secondary battery, the parameter estimation device comprising:
a collection unit configured to collect a current and a voltage of the secondary battery when charging or discharging of the secondary battery has been performed on the basis of a current pattern;
a collective estimation unit configured to collectively estimate the parameters of the equivalent circuit of the secondary battery on the basis of the current and the voltage collected by the collection unit; and
an output unit configured to output the parameters estimated by the collective estimation unit.

18. (canceled)

19. A parameter estimation method for estimating parameters of an equivalent circuit of a secondary battery, the parameter estimation method comprising:
acquiring a current and a voltage of the secondary battery when charging or discharging of the secondary battery has been performed on the basis of a current pattern;
sequentially estimating the parameters of the equivalent circuit of the secondary battery on the basis of the acquired current and voltage;
collecting the current and the voltage of the secondary battery when charging or discharging of the secondary battery has been performed on the basis of the current pattern;
collectively estimating the parameters of the equivalent circuit of the secondary battery on the basis of the collected current and voltage; and
updating, when the collectively estimated parameters have been acquired, the sequentially estimated parameters with the collectively estimated parameters.
